(19) United States
(12) Patent Application Publication
(10) Pub. No.: US 2026/0323958 A1
(43) Pub. Date: Oct. 15, 2026

(54) SEMICONDUCTOR MEMORY DEVICE AND FABRICATION METHOD THEREOF

(71) Applicant: UNITED MICROELECTRONICS CORP., Hsin-Chu City (TW)

(72) Inventors: Chia-Chang Hsu, Kaohsiung City (TW); Chien-Cheng Liao, Taichung City (TW)

(73) Assignee: UNITED MICROELECTRONICS CORP., Hsin-Chu City (TW)

(21) Appl. No.: 19/204,628

(22) Filed: May 12, 2025

(30) Foreign Application Priority Data
Apr. 14, 2025 (TW) 114113958

(51) Int. Cl. H10B 63/00

(52) U.S. Cl. CPC H10B 63/80

(57) ABSTRACT

A semiconductor memory device includes a substrate having a logic region and a memory region thereon; a first dielectric layer on the substrate, covering the logic region and the memory region; a first contact and a second contact disposed in the first dielectric layer within the logic region and the memory region, respectively; a dielectric mask layer disposed over the first dielectric layer within the logic region; a memory stack structure disposed on the second contact within the memory region; and a second dielectric layer disposed on the memory stack structure and the first dielectric layer within the memory region, and on the dielectric mask layer within the logic region.

### BACKGROUND OF THE INVENTION

### 1. Field of the Invention

This invention relates to the field of semiconductor technology, and more particularly to an improved resistive random access memory (RRAM) structure and its manufacturing method.

### 2. Description of the Prior Art

Resistive random-access memory (RRAM) cells typically consist of two conductive electrodes sandwiching a switching layer, which allows the memory cell to switch between a high-resistance state (HRS), representing a logical “0,” and a low-resistance state (LRS), representing a logical “1.”

RRAM operation relies on the formation and breaking of conductive filaments within the switching layer. These filaments create low-resistance paths between the electrodes, driving the cell to the LRS. However, the unpredictable number and distribution of these filaments lead to unstable electrical characteristics, such as variations in the voltages required to set (switch to LRS) or reset (switch to HRS) the cell.

The current challenge in RRAM manufacturing is that during the etching of the resistive switching electrode (RSE) within the memory region, the etchant also damages the tungsten contacts in the logic region. Therefore, there is a need for further improvement of the existing manufacturing process.

### SUMMARY OF THE INVENTION

It is one objective of the present invention to provide an improved resistive random access memory (RRAM) structure and its manufacturing method to address the deficiencies or shortcomings of the existing technology.

One aspect of the invention provides a semiconductor memory device including a substrate having a logic region and a memory region thereon; a first dielectric layer disposed on the substrate and covering the logic region and the memory region; a first contact and a second contact disposed within the first dielectric layer and located in the logic region and the memory region, respectively; a dielectric mask layer disposed on the first dielectric layer within the logic region; a memory stack structure disposed on the second contact and located within the memory region; and a second dielectric layer disposed on the memory stack structure and the first dielectric layer within the memory region, and disposed on the dielectric mask layer within the logic region.

According to some embodiments, the dielectric mask layer covers the logic region but does not extend onto the memory region.

According to some embodiments, a thickness of the dielectric mask layer is 600-1000 angstroms.

According to some embodiments, the dielectric mask layer comprises silicon oxycarbide.

According to some embodiments, the dielectric mask layer is in direct contact with the first dielectric layer.

According to some embodiments, the second dielectric layer comprises a low-k dielectric material.

According to some embodiments, the memory stack structure comprises a bottom electrode layer, a switching layer disposed on the bottom electrode layer, and a top electrode layer disposed on the switching layer, wherein the bottom electrode layer is electrically connected to the second contact.

According to some embodiments, the first contact and the second contact are tungsten contacts.

According to some embodiments, the semiconductor memory device further includes a first sidewall spacer disposed on a sidewall of the dielectric mask layer at a boundary between the logic region and the memory region; and a second sidewall spacer disposed on a sidewall of the memory stack structure within the memory region.

According to some embodiments, the semiconductor memory device further includes a first conductive via disposed in the second dielectric layer and the dielectric mask layer within the logic region, wherein the first conductive via is electrically connected to the first contact; a first metal layer disposed on the second dielectric layer and in direct contact with the first conductive via; a second conductive via disposed in the second dielectric layer within the memory region, wherein the second conductive via is electrically connected to the second contact; and a second metal layer disposed on the second dielectric layer and in direct contact with the second conductive via.

Another aspect of the invention provides a method of forming a semiconductor memory device. A substrate having a logic region and a memory region thereon is provided. A first dielectric layer is formed on the substrate. The first dielectric layer covers the logic region and the memory region. A first contact and a second contact are formed in the first dielectric layer, which are located in the logic region and the memory region, respectively. A dielectric mask layer is formed on the first contact within the logic region. A memory stack structure is formed on the second contact within the memory region. A second dielectric layer is formed on the memory stack structure and the first dielectric layer within the memory region, and on the dielectric mask layer within the logic region.

According to some embodiments, the dielectric mask layer covers the logic region but does not extend onto the memory region.

According to some embodiments, a thickness of the dielectric mask layer is 600-1000 angstroms.

According to some embodiments, the dielectric mask layer comprises silicon oxycarbide.

According to some embodiments, the dielectric mask layer is in direct contact with the first dielectric layer.

According to some embodiments, the second dielectric layer comprises a low-k dielectric material.

According to some embodiments, the memory stack structure comprises a bottom electrode layer, a switching layer disposed on the bottom electrode layer, and a top electrode layer disposed on the switching layer, wherein the bottom electrode layer is electrically connected to the second contact.

According to some embodiments, the first contact and the second contact are tungsten contacts.

According to some embodiments, the method further includes the steps of forming a first sidewall spacer on a sidewall of the dielectric mask layer at a boundary between the logic region and the memory region; and forming a second sidewall spacer on a sidewall of the memory stack structure within the memory region.

According to some embodiments, the method further includes the steps of forming a first conductive via in the second dielectric layer and the dielectric mask layer within the logic region, wherein the first conductive via is electrically connected to the first contact; forming a first metal layer on the second dielectric layer and in direct contact with the first conductive via; forming a second conductive via in the second dielectric layer within the memory region, wherein the second conductive via is electrically connected to the second contact; and forming a second metal layer on the second dielectric layer and in direct contact with the second conductive via.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 7 are schematic diagrams illustrating a method of forming a semiconductor memory device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

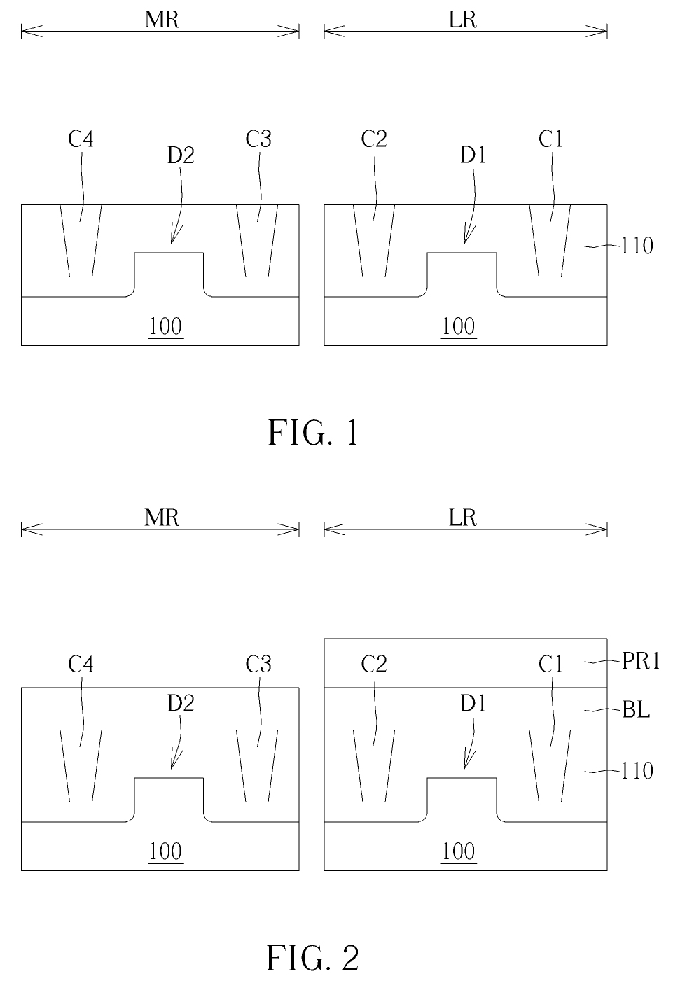

Please refer to FIGS. 1-7, which are schematic diagrams illustrating a method of forming a semiconductor memory device according to an embodiment of the present invention. As shown in FIG. 1, a substrate 100 is first provided, for example, a silicon substrate, having a logic region LR and a memory region MR. Next, a chemical vapor deposition (CVD) process can be performed to form a dielectric layer 110, such as a silicon oxide layer, on the substrate 100, covering the logic region LR and the memory region MR.

According to an embodiment of the present invention, circuit elements D1 can be formed on the substrate 100 within the logic region LR, and circuit elements D2 can be formed on the substrate 100 within the memory region MR. For example, the circuit elements D1 and D2 may include transistors, but are not limited thereto. According to an embodiment of the present invention, the dielectric layer 110 covers the circuit elements D1 and D2.

Next, photolithography, etching, deposition, and chemical mechanical polishing (CMP) processes, etc., can be performed to simultaneously form contacts C1-C4 in the dielectric layer 110 within the logic region LR and the memory region MR, wherein contacts C1-C2 are located within the logic region LR, and contacts C3-C4 are located within the memory region MR. According to an embodiment of the present invention, contacts C1-C4 are, for example, tungsten contacts. The contacts C1-C4 can be electrically connected to the corresponding terminals of circuit elements D1 and D2, such as the drain or source, respectively. At this point, the top surfaces of each contact C1-C4 are coplanar with the top surface of the dielectric layer 110.

Next, as shown in FIG. 2, a dielectric layer BL, for example, a silicon oxycarbide layer with a thickness of about 600-1000 angstroms, is deposited over the substrate 100 in a blanket manner. A photoresist pattern PR1 is then formed on the dielectric layer BL, covering the logic region LR but not covering the memory region MR.

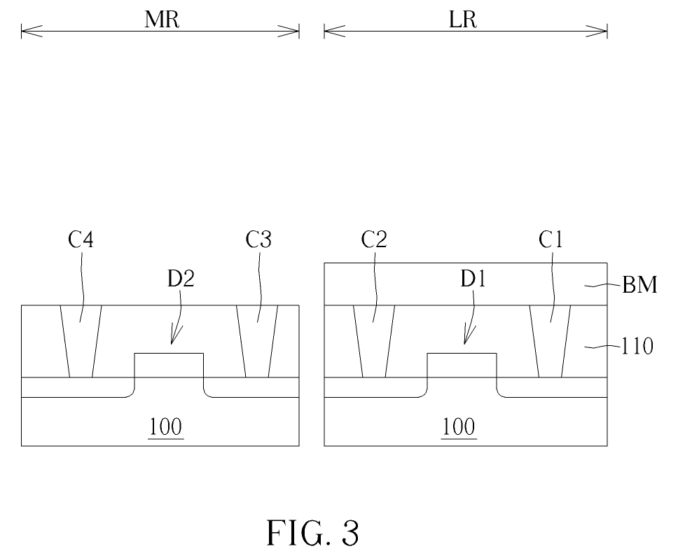

Next, as shown in FIG. 3, an anisotropic dry etching process is performed to remove the dielectric layer BL not covered by the photoresist pattern PR1, leaving only the dielectric layer BL located on the logic region LR, forming a dielectric mask layer BM. According to an embodiment of the present invention, the dielectric mask layer BM is in direct contact with the dielectric layer 110. At this point, the contacts C1-C2 located within the logic region LR are covered by the dielectric mask layer BM. According to an embodiment of the present invention, the dielectric mask layer BM covers the logic region LR but does not extend onto the memory region MR. Subsequently, the remaining photoresist pattern PR1 is removed.

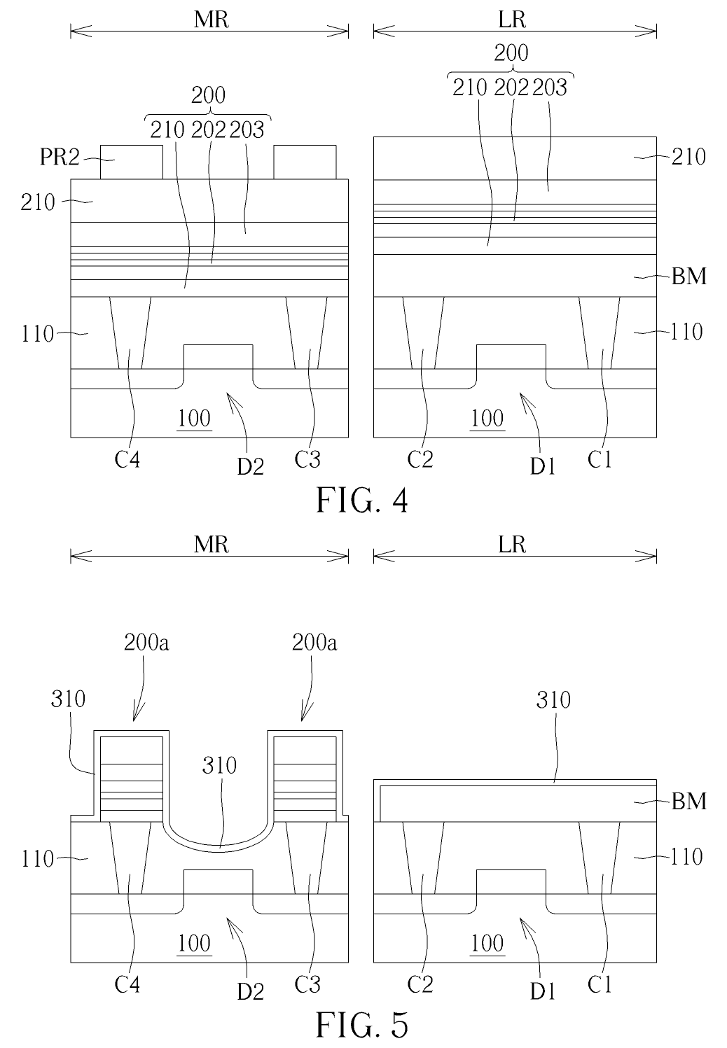

As shown in FIG. 4, a deposition process is then performed to form a memory stack film 200 on the substrate 100. According to an embodiment of the present invention, the memory stack film 200 includes, for example, a bottom electrode layer 201, a switching layer 202 disposed on the bottom electrode layer 201, and a top electrode layer 203 disposed on the switching layer 202. The bottom electrode layer 201 is in direct contact with the contacts C3-C4. Within the logic region LR, the memory stack film 200 is deposited on the dielectric mask layer BM and therefore does not directly contact the contacts C1-C2.

Next, a photoresist pattern PR2 is formed on the memory stack film 200 within the memory region MR. According to an embodiment of the present invention, an anti-reflective coating layer 210 may optionally be formed between the photoresist pattern PR2 and the memory stack film 200.

As shown in FIG. 5, an anisotropic dry etching process is then performed to etch the anti-reflective coating layer 210 and the memory stack film 200 not covered by the photoresist pattern PR2 until the dielectric mask layer BM is exposed. At this point, a plurality of patterned memory stack structures 200a are formed in the memory region MR, each located on a corresponding contact C3-C4. Due to over-etching, the surface of the dielectric layer 110 in the memory region MR will be slightly recessed. However, the surfaces of the dielectric layer 110 and the contacts C1-C2 in the logic region LR are protected by the dielectric mask layer BM and will not be recessed, maintaining a flat top surface.

Next, a spacer material layer 310, for example, a silicon nitride layer, is deposited over the memory region MR and logic region LR in a blanket manner. The spacer material layer 310 is conformally deposited on the surfaces of the dielectric mask layer BM, the memory stack structures 200a, and the dielectric layer 110.

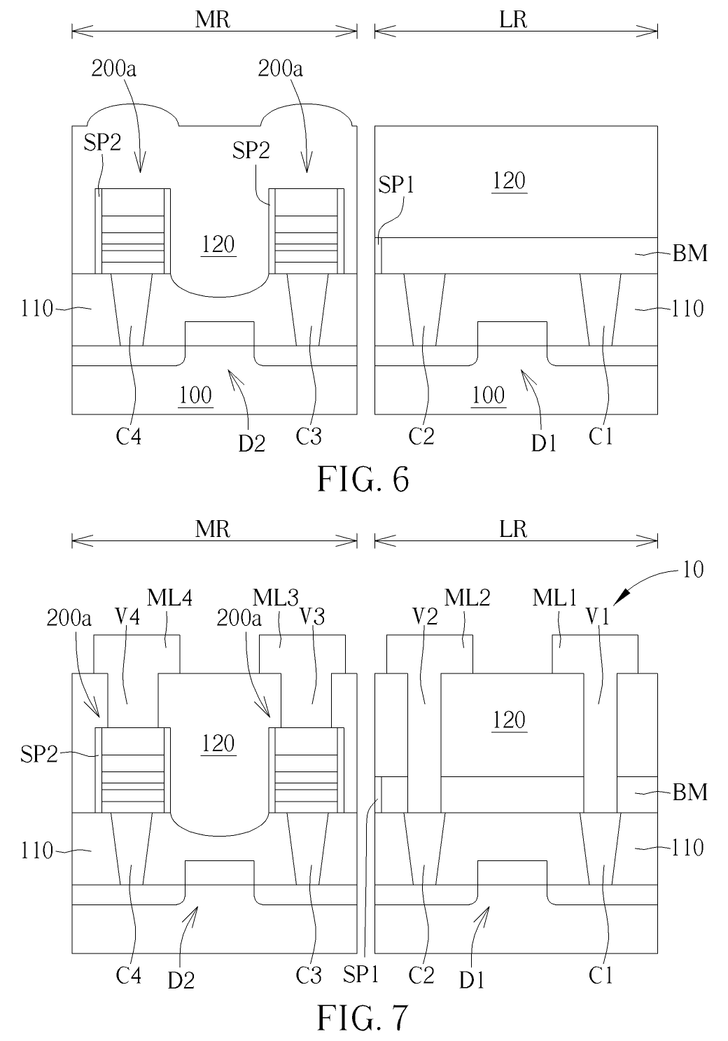

As shown in FIG. 6, an anisotropic dry etching process is then performed to form sidewall spacers SP1 on the sidewalls of the dielectric mask layer BM at the boundary between the logic region LR and the memory region MR, and to form sidewall spacers SP2 on the sidewalls of the memory stack structures 200a within the memory region MR. Next, a dielectric layer 120 is formed on the memory stack structures 200a and the dielectric layer 110 in the memory region MR, and on the dielectric mask layer BM in the logic region LR. According to an embodiment of the present invention, the dielectric layer 120 may include, for example, a low-k dielectric material.

As shown in FIG. 7, the dielectric layer 120 can then undergo a planarization process. Subsequently, conductive vias V1-V2 are formed in the dielectric layer 120 and the dielectric mask layer BM within the logic region LR, wherein the conductive vias V1-V2 are electrically connected to the contacts C1-C2, respectively. Simultaneously, conductive vias V3-V4 are formed in the dielectric layer 120 within the memory region MR, wherein the conductive vias V3-V4 are electrically connected to the top electrode layers 203 of the memory stack structures 200a, respectively.

Subsequently, metal layers ML1-ML4 are formed on the dielectric layer 120 and are in direct contact with the conductive vias V1-V4, thus completing the fabrication of the semiconductor memory device 10. According to an embodiment of the present invention, the conductive vias V3-V4 and the metal layers ML1-ML4 can be formed using a copper damascene process.

Structurally, as shown in FIG. 7, the semiconductor memory device 10 includes a substrate 100 having a logic region LR and a memory region MR, a dielectric layer 110 located on the substrate 100 and covering the logic region LR and the memory region MR, contacts C1-C2 and contacts C3-C4 disposed within the dielectric layer 110 and located in the logic region LR and the memory region MR, respectively, a dielectric mask layer BM disposed on the dielectric layer 110 within the logic region LR, a memory stack structure 200a disposed on the contacts C3-C4 within the memory region MR, and a dielectric layer 120 disposed on the memory stack structure 200a and the dielectric layer 110 within the memory region MR, and disposed on the dielectric mask layer BM within the logic region LR.

According to an embodiment of the present invention, the dielectric mask layer BM covers the logic region LR but does not extend onto the memory region MR. According to an embodiment of the present invention, the thickness of the dielectric mask layer BM is about 600-1000 angstroms. According to an embodiment of the present invention, the dielectric mask layer BM may include, for example, silicon oxycarbide. According to an embodiment of the present invention, the dielectric mask layer BM is in direct contact with the dielectric layer 110. According to an embodiment of the present invention, the dielectric layer 120 may include, for example, a low-k dielectric material.

According to an embodiment of the present invention, the memory stack structure 200a includes a bottom electrode layer 201, a switching layer 202 disposed on the bottom electrode layer 201, and a top electrode layer 203 disposed on the switching layer 202, wherein the bottom electrode layer 201 is electrically connected to the contacts C3-C4.

According to an embodiment of the present invention, the contacts C1-C2 and the contacts C3-C4 are tungsten contacts.

According to an embodiment of the present invention, the semiconductor memory device 10 further includes: sidewall spacers SP1 disposed on the sidewalls of the dielectric mask layer BM at the boundary between the logic region LR and the memory region MR; and sidewall spacers SP2 disposed on the sidewalls of the memory stack structure 200a within the memory region MR.

According to an embodiment of the present invention, the semiconductor memory device 10 further includes: conductive vias V1-V2 disposed in the dielectric layer 120 and the dielectric mask layer BM within the logic region LR, wherein the conductive vias V1-V2 are electrically connected to the contacts C1-C2, respectively; and metal layers ML1-ML2 disposed on the dielectric layer 120 and in direct contact with the conductive vias V1-V2.

According to an embodiment of the present invention, the semiconductor memory device 10 further includes: conductive vias V3-V4 disposed in the dielectric layer 120 within the memory region MR, wherein the conductive vias V3-V4 are electrically connected to the contacts C3-C4; and metal layers ML3-ML4 disposed on the dielectric layer 120 and in direct contact with the conductive vias V3-V4.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory device, comprising:
a substrate having a logic region and a memory region thereon;
a first dielectric layer disposed on the substrate and covering the logic region and the memory region;
a first contact and a second contact disposed within the first dielectric layer and located in the logic region and the memory region, respectively;
a dielectric mask layer disposed on the first dielectric layer within the logic region;
a memory stack structure disposed on the second contact and located within the memory region; and
a second dielectric layer disposed on the memory stack structure and the first dielectric layer within the memory region, and disposed on the dielectric mask layer within the logic region.

2. The semiconductor memory device according to claim 1, wherein the dielectric mask layer covers the logic region but does not extend onto the memory region.

3. The semiconductor memory device according to claim 1, wherein a thickness of the dielectric mask layer is 600-1000 angstroms.

4. The semiconductor memory device according to claim 1, wherein the dielectric mask layer comprises silicon oxycarbide.

5. The semiconductor memory device according to claim 1, wherein the dielectric mask layer is in direct contact with the first dielectric layer.

6. The semiconductor memory device according to claim 1, wherein the second dielectric layer comprises a low-k dielectric material.

7. The semiconductor memory device according to claim 1, wherein the memory stack structure comprises a bottom electrode layer, a switching layer disposed on the bottom electrode layer, and a top electrode layer disposed on the switching layer, wherein the bottom electrode layer is electrically connected to the second contact.

8. The semiconductor memory device according to claim 1, wherein the first contact and the second contact are tungsten contacts.

9. The semiconductor memory device according to claim 1, further comprising:
a first sidewall spacer disposed on a sidewall of the dielectric mask layer at a boundary between the logic region and the memory region; and
a second sidewall spacer disposed on a sidewall of the memory stack structure within the memory region.

10. The semiconductor memory device according to claim 1, further comprising:
a first conductive via disposed in the second dielectric layer and the dielectric mask layer within the logic region, wherein the first conductive via is electrically connected to the first contact;
a first metal layer disposed on the second dielectric layer and in direct contact with the first conductive via;
a second conductive via disposed in the second dielectric layer within the memory region, wherein the second conductive via is electrically connected to the second contact; and
a second metal layer disposed on the second dielectric layer and in direct contact with the second conductive via.

11. A method of forming a semiconductor memory device, comprising:
providing a substrate having a logic region and a memory region thereon;
forming a first dielectric layer on the substrate, covering the logic region and the memory region;
forming a first contact and a second contact in the first dielectric layer, located in the logic region and the memory region, respectively;
forming a dielectric mask layer on the first contact within the logic region;
forming a memory stack structure on the second contact within the memory region; and
forming a second dielectric layer on the memory stack structure and the first dielectric layer within the memory region, and on the dielectric mask layer within the logic region.

12. The method according to claim 11, wherein the dielectric mask layer covers the logic region but does not extend onto the memory region.

13. The method according to claim 11, wherein a thickness of the dielectric mask layer is 600-1000 angstroms.

14. The method according to claim 11, wherein the dielectric mask layer comprises silicon oxycarbide.

15. The method according to claim 11, wherein the dielectric mask layer is in direct contact with the first dielectric layer.

16. The method according to claim 11, wherein the second dielectric layer comprises a low-k dielectric material.

17. The method according to claim 11, wherein the memory stack structure comprises a bottom electrode layer, a switching layer disposed on the bottom electrode layer, and a top electrode layer disposed on the switching layer, wherein the bottom electrode layer is electrically connected to the second contact.

18. The method according to claim 11, wherein the first contact and the second contact are tungsten contacts.

19. The method according to claim 11, further comprising:
forming a first sidewall spacer on a sidewall of the dielectric mask layer at a boundary between the logic region and the memory region; and
forming a second sidewall spacer on a sidewall of the memory stack structure within the memory region.

20. The method according to claim 11, further comprising:
forming a first conductive via in the second dielectric layer and the dielectric mask layer within the logic region, wherein the first conductive via is electrically connected to the first contact;
forming a first metal layer on the second dielectric layer and in direct contact with the first conductive via;
forming a second conductive via in the second dielectric layer within the memory region, wherein the second conductive via is electrically connected to the second contact; and
forming a second metal layer on the second dielectric layer and in direct contact with the second conductive via.
